(19) United States
(12) Patent Application Publication
(10) Pub. No.: US 2020/0411340 A1
(43) Pub. Date: Dec. 31, 2020

(54) HEATING APPARATUS, HEATING METHOD, AND SUBSTRATE PROCESSING APPARATUS

(71) Applicant: TOKYO ELECTRON LIMITED, Tokyo (JP)

(72) Inventors: Taro IKEDA, Nirasaki City (JP); Naoki WATANABE, Nirasaki City (JP); Tatsuo HATANO, Nirasaki City (JP); Nobuhiko YAMAMOTO, Nirasaki City (JP); Eiki KAMATA, Nirasaki City (JP)

(21) Appl. No.: 16/912,203

(22) Filed: Jun. 25, 2020

(30) Foreign Application Priority Data
Jun. 28, 2019 (JP) 2019-120974

(51) Int. Cl. H01L 21/67; H05B 6/72; H05B 6/64; H05B 1/02; H01L 21/324

(52) U.S. Cl. CPC H01L 21/67115; H05B 6/72; H01L 21/324; H05B 1/0233; H05B 6/6408; H05B 6/6491

(57) ABSTRACT

An apparatus for heating a heating target object includes: a heating member for supporting the heating target object; an electromagnetic wave irradiation part for irradiating an electromagnetic wave to an irradiation surface of the heating member, which is opposite to a surface supporting the heating target object; and a controller. The electromagnetic wave irradiation part includes: an electromagnetic wave output part for outputting the electromagnetic wave; and an antenna unit. The antenna unit includes antenna modules each having an antenna for radiating radiate the electromagnetic wave and a phase shifter for adjusting phase of the electromagnetic wave radiated from the antenna. The controller controls the phase shifters of the antenna modules so that phases of electromagnetic waves radiated from a plurality of the antenna are condensed on an arbitrary portion of the heating member by interference, and a condensed portion of the electromagnetic waves is scanned on the irradiation surface.

### CROSS-REFERENCE TO RELATED APPLICATION

This application is based upon and claims the benefit of priority from Japanese Patent Application No. 2019-120974, filed on Jun. 28, 2019, the entire contents of which are incorporated herein by reference.

### TECHNICAL FIELD

The present disclosure relates to a heating apparatus, a heating method, and a substrate processing apparatus.

### BACKGROUND

In a manufacturing process of a semiconductor device, there is a process of heating a substrate, such as a film-forming process, an annealing process or the like. As an apparatus for heating a substrate, there is known a resistive heater that heats a substrate on a stage by heat generated from a resistive heater embedded in the stage (for example, Patent Document 1). Further, there is known a heating apparatus that heats a substrate by a lamp (for example, Patent Document 2).

### PRIOR ART DOCUMENTS

### Patent Documents

Patent Document 1: Japanese laid-open publication No. 2007-002298
Patent Document 2: Japanese laid-open publication No. H6-224135

### SUMMARY

According to one embodiment of the present disclosure, there is provided a heating apparatus for heating a heating target object, which includes: a heating member configured to support the heating target object and made of an electromagnetic wave absorber; an electromagnetic wave irradiation part configured to irradiate an electromagnetic wave to an irradiation surface of the heating member positioned opposite to a surface supporting the heating target object; and a controller, wherein the electromagnetic wave irradiation part includes: an electromagnetic wave output part configured to output the electromagnetic wave; and an antenna unit constituting a phased array antenna, the antenna unit further includes: a plurality of antenna modules each having an antenna configured to radiate the electromagnetic wave and a phase shifter configured to adjust a phase of the electromagnetic wave radiated from the antenna, and the controller is configured to control the phase shifters of the plurality of antenna modules so that phases of electromagnetic waves radiated from a plurality of the antenna are condensed on an arbitrary portion of the heating member by interference, and a condensed portion of the electromagnetic waves is scanned on the irradiation surface of the heating member.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a cross-sectional view illustrating a heating apparatus according to an embodiment of the present disclosure.

FIG. 2 is a cross-sectional view schematically illustrating arrangement of antenna modules in the heating apparatus in FIG. 1.

FIG. 3 is a block diagram illustrating a configuration of an amplifier part used for each antenna module in the heating apparatus in FIG. 1.

FIG. 4 is a cross-sectional view illustrating an example in which a modified monopole antenna is used as an antenna.

FIG. 5 is a block diagram illustrating a configuration of an electromagnetic wave output part in the heating apparatus in FIG. 1.

FIG. 6 is a cross-sectional view illustrating a state in which an electromagnetic wave is condensed on a predetermined position of a heating member by phase control of the electromagnetic wave.

FIG. 7 is a schematic diagram illustrating a principle of condensing the electromagnetic wave.

FIG. 8 is a diagram expressing a phase difference δ(x) on coordinates as a function of x.

FIG. 9 is a schematic diagram illustrating arrangement of respective antennas and a phase difference by the antennas.

FIG. 10 is a schematic diagram illustrating a state in which a condensed portion of the heating member is scanned by phase control.

FIG. 11 is a diagram illustrating a model when condensing of the electromagnetic wave by the phase control is confirmed by electromagnetic field simulation.

FIG. 12 is a diagram illustrating an example in which an electromagnetic wave is condensed on an outer portion of the heating member (substrate) by the electromagnetic field simulation.

FIG. 13 is a diagram illustrating an example in which an electromagnetic wave is condensed on a central portion of the heating member (substrate) by the electromagnetic field simulation.

FIG. 14 is a cross-sectional view illustrating an example of a substrate processing apparatus including the heating apparatus according to an embodiment of the present disclosure.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

### <Configuration of Heating Apparatus>

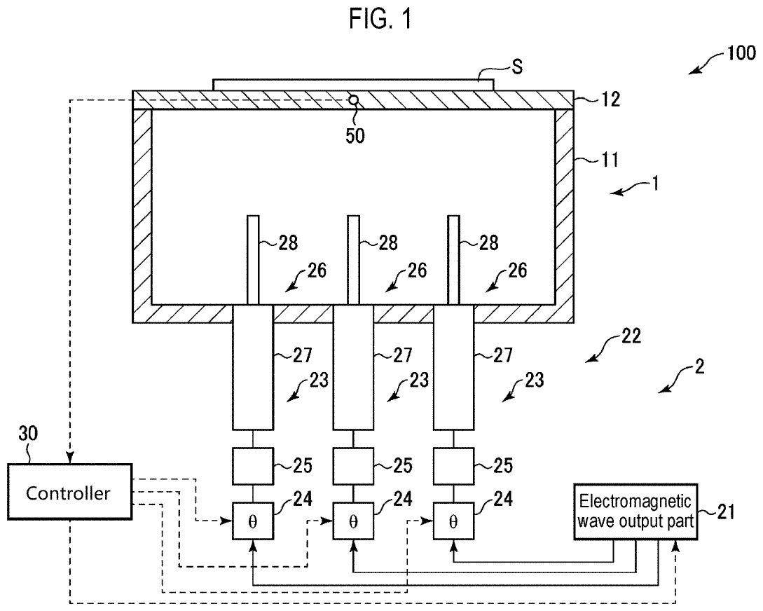

FIG. 1 is a cross-sectional view illustrating a heating apparatus according to an embodiment of the present disclosure.

A heating apparatus 100 of the present embodiment is provided to heat a substrate as a heating target object, and includes a stage housing 1 and an electromagnetic wave irradiation part 2.

The stage housing 1 includes a main body 11 having an opening at its upper portion, and a heating member 12 installed to close the opening of the main body 11 and configured to support a substrate S. The heating member 12 is made of an electromagnetic wave absorber which absorbs an electromagnetic wave, for example, a carbon-based material such as graphite. A temperature sensor 50 such as a thermocouple or the like is installed in the heating member 12. A plurality of temperature sensors 50 may be installed.

The electromagnetic wave irradiation part 2 irradiates the electromagnetic wave from below to the heating member 12 so as to heat the heating member 12 with the electromagnetic wave and to heat the substrate S with the heat, and includes an electromagnetic wave output part 21 for outputting the electromagnetic wave, and an antenna unit 22.

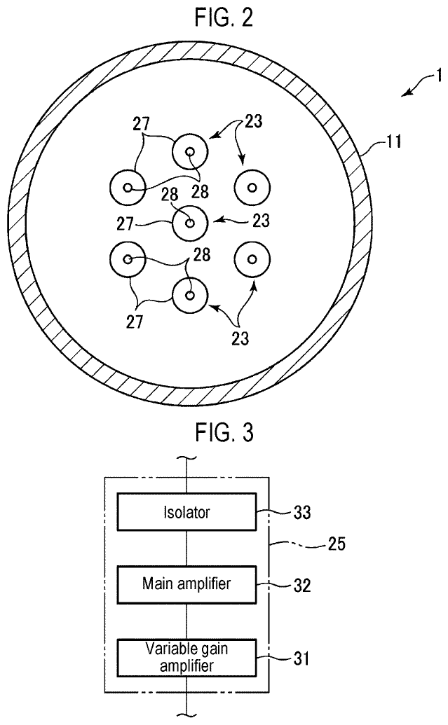

The antenna unit 22 has a plurality of antenna modules 23 for irradiating the substrate S with the electromagnetic wave. The plurality of antenna modules 23 are installed at regular intervals with respect to the substrate S. The number of antenna modules 23 may be set to an appropriate number so that the substrate S can be properly heated. In this example, seven antenna modules 23 are installed as illustrated in FIG. 2.

Each of the antenna modules 23 has an antenna which radiates the electromagnetic wave, and is configured to change the phase of the electromagnetic wave radiated from the antenna. Then, by controlling the phase of the electromagnetic wave radiated from each antenna module 23 to cause interference, the electromagnetic wave may be condensed and irradiated on an arbitrary portion of the heating member 12. That is, the antenna unit 22 serves as a phased array antenna.

Specifically, each of the antenna modules 23 includes a phase shifter 24, an amplifier part 25, and an electromagnetic wave radiation mechanism 26.

The phase shifter 24 serves to change the phase of the electromagnetic wave, and is configured to advance or delay the phase of the electromagnetic wave radiated from the antenna 28 so as to adjust the phase. By adjusting the phase using the phase shifter 24 of each antenna module 23, the electromagnetic wave can be condensed on a desired position of the heating member 12 using interference of the electromagnetic wave.

The amplifier part 25 is configured to have a variable gain amplifier 31, a main amplifier 32 constituting a solid state amplifier, and an isolator 33 sequentially arranged from the side of the phase shifter 24, as illustrated in FIG. 3.

The variable gain amplifier 31 is an amplifier for adjusting variations of the individual antenna modules 23 or adjusting the electromagnetic wave intensity by adjusting a power level of the electromagnetic wave to be inputted to the main amplifier 32.

The main amplifier 32 constituting the solid state amplifier may be configured to have, for example, an input matching circuit, a semiconductor amplifying element, an output matching circuit, and a high-Q resonance circuit.

The isolator 33 isolates the electromagnetic wave which is reflected by the electromagnetic wave radiation mechanism 26 and is to be oriented to the main amplifier 32, and has a circulator and a dummy load (coaxial terminator). The circulator guides the reflected electromagnetic wave to the dummy load, and the dummy load converts the reflected electromagnetic wave guided by the circulator into heat.

The electromagnetic wave radiation mechanism 26 includes a waveguide 27 having a coaxial structure, and an antenna 28 extending from the waveguide 27. A tuner having two slags movable along the waveguide 27 may be installed in the waveguide 27. By moving the two slags, an impedance on the load side is matched with an impedance on a power source side. The antenna 28 radiates the electromagnetic wave. An antenna capable of radiating the electromagnetic wave not only in a straight direction but also in a wide range direction having a horizontal component may be used. As the antenna 28, copper, brass, silver-plated aluminum, or the like may be used. In the illustrated example, the antenna 28 is a monopole antenna, and is arranged perpendicular to the substrate S. However, any antenna may be used as the antenna 28 as long as it can cause a portion on which the electromagnetic wave is condensed by interference of the electromagnetic wave. As an example, a helical antenna, a patch antenna or the like may be used as the antenna 28.

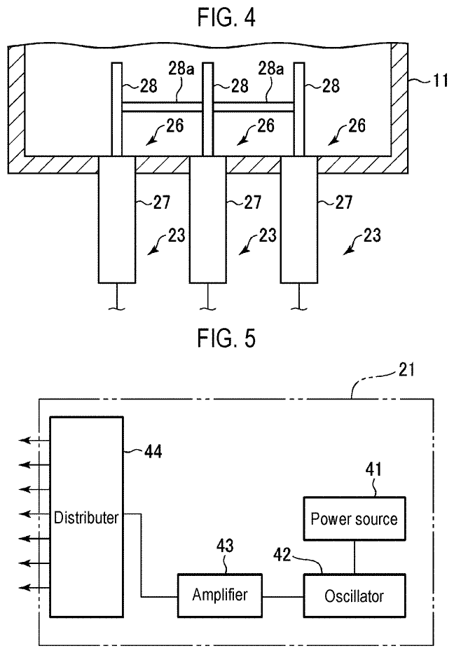

When a monopole antenna is used as the antenna, as illustrated in FIG. 4, a modified monopole antenna in which adjacent antennas 28 are connected with each other by a conductive connection member 28a may be used. By using such a modified monopole antenna, it is possible to suppress reception of electromagnetic waves from other antennas, to reduce interference of electromagnetic waves between the antennas, and to improve performance.

As illustrated in FIG. 5, the electromagnetic wave output part 21 has a power source 41, an oscillator 42, an amplifier 43 for amplifying an oscillated electromagnetic wave, and a distributor 44 for distributing the amplified electromagnetic wave to each antenna module 23, and outputs the electromagnetic wave to each antenna module 23.

The oscillator 42 oscillates the electromagnetic wave having a predetermined frequency (e.g., 860 MHz) by, for example, a phase locked loop (PLL) manner. The distributor 44 distributes the amplified electromagnetic wave while taking an impedance matching between impedance on the input side and impedance the output side such that the loss of the electromagnetic wave occurs as little as possible. As the frequency of the electromagnetic wave, a desired frequency in the range of 500 MHz to 3 GHz may be used in addition to 860 MHz.

The respective components of the heating apparatus 100 are configured to be controlled by a controller 30 including a CPU. The controller 30 includes a storage part which stores a control parameter or a process recipe of the heating apparatus 100, an input means, a display, and the like. The controller 30 controls the power of the electromagnetic wave output part 21 based on a signal provided from the temperature sensor 50. Furthermore, the controller 30 controls the change of the phase of the electromagnetic wave performed by the phase shifter 24 of each antenna module 23, so as to control a portion of the heating member 12 on which the electromagnetic wave is condensed by interference. For example, the controller 30 controls the condensed portion of the electromagnetic wave to be uniformly scanned over the entire surface of the heating member 12, so that the heating member 12 can be heated to have a uniform temperature distribution. Furthermore, when the plurality of temperature sensors 50 are arranged, the temperature at each position is measured by the respective temperature sensor 50. Based on the measured temperature signal, a scanning speed is changed depending on the position of the heating member 12, thus realizing finer temperature control. In some embodiments, a specific temperature distribution, such as raising the temperature of a specific portion, may be formed by controlling the scanning speed of the condensed portion of the heating member 12 to be intentionally changed.

The control of the phase shifter 24 by the controller 30 may be performed by, for example, storing a plurality of tables indicating relationships between the phase of each antenna module and the condensed position of the electromagnetic wave in advance in the storage part, and quickly switching the tables.

### <Operation of the Heating Apparatus>

Next, an operation of the heating apparatus 100 configured as above will be described.

The substrate S is placed on the heating member 12 made of an electromagnetic wave absorbing material, and an electromagnetic wave is irradiated from the electromagnetic wave irradiation part 2 disposed below the substrate S toward the lower surface of the heating member 12 to heat the heating member 12. The heating member 12 absorbs the electromagnetic wave to raise the temperature. Therefore, the substrate S can be heated by the heating member 12.

The electromagnetic wave irradiation part 2 supplies the electromagnetic wave from the electromagnetic wave output part 21 to each antenna module 23 of the antenna unit 22. Then, the supplied electromagnetic wave is radiated from the antenna 28 of the antenna module 23. The electromagnetic wave radiated from each antenna 28 is irradiated to the heating member 12.

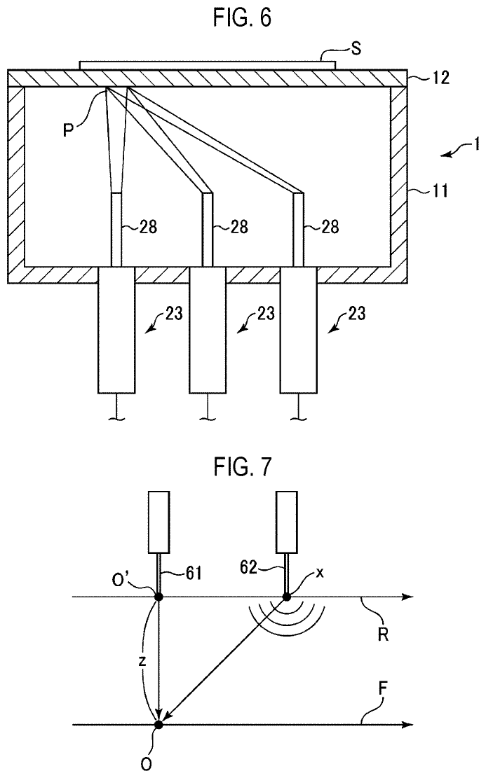

At this time, the antenna unit 22 serves as a phased array antenna. By controlling the phase of the electromagnetic wave radiated from the antenna 28 of each antenna module 23, it is possible to condense the electromagnetic wave on an arbitrary portion P (condensed portion P) of the heating member 12, as illustrated in FIG. 6. In other words, the electric field intensity can be locally enhanced. Accordingly, the condensed portion can be heated at a very high speed.

The condensing of the electromagnetic wave at this time is obtained using the interference of the electromagnetic wave by the phase control, and the scanning of the condensed portion can also be performed only by the phase control without accompanying mechanical operation, so that the condensing and scanning can be performed at a very high speed. In principle, the condensing and scanning can be performed at a speed substantially equal to the frequency of the electromagnetic wave.

Since the electromagnetic wave can be condensed by the phase control in this way, the temperature of the condensed portion can be quickly raised. Further, since the condensed portion can be quickly scanned, the entire substrate S can be efficiently heated at a very high speed. At this time, the uniform heating can be performed by scanning the condensed portion at a uniform speed. Further, it is possible to freely adjust the temperature distribution by changing the scanning speed of the condensed portion depending on the position of the heating member 12.

Next, the principle of condensing the electromagnetic wave will be described.

The electromagnetic wave radiated from the antenna 28 basically spreads at every angle and is irradiated to the heating member 12. At this time, as illustrated in FIG. 7, a distance between an irradiation surface F of the electromagnetic wave irradiated to the heating member 12 and a radiation surface R on which electromagnetic wave radiation positions of the plurality of antennas 28 exist is set to z. A condensed position of the electromagnetic wave on the irradiation surface F is set to O, and phases of electromagnetic waves radiated from a first antenna 61 on which the electromagnetic wave radiation position exists at 0′ corresponding to O on the radiation surface R and a second antenna 62 on which the electromagnetic wave irradiation position exists at a position x away from the position O′ are considered. A distance between the condensed position O and the electromagnetic wave radiation position O′ of the first antenna 61 is z, and a distance between the condensed position O and an electromagnetic wave radiation position x of the second antenna 62 is (x²+z²)^{1/2}. When a wave number of the electromagnetic wave is k (2π/λ when the wavelength of the electromagnetic wave is λ), the phase at the condensed position O of the antenna radiated from the first antenna is represented by kz and the phase at the condensed position O radiated from the second antenna is represented by k(x₂+z²)^{1/2}. Assuming that a phase difference between the two phases is δ(x), the following equation is established.

k(x²+z²)^{1/2}−δ(x)=kz

δ(x)=k{(x²+z²)^{1/2}−z}

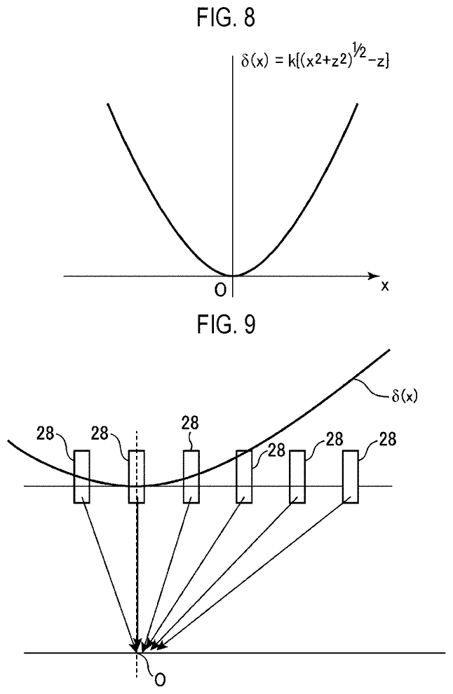

If δ(x) is expressed on coordinates as a function of x, the result as illustrated in FIG. 8 is obtained.

Therefore, in order to condense the electromagnetic wave radiated from the second antenna on the condensed position O, the phase shifter 24 may delay the phase of the electromagnetic wave radiated from the second antenna by δ(x) from the phase of the electromagnetic wave radiated from the first antenna so as to match the phases. That is, by matching the phases, the electromagnetic waves are strengthened and condensed on the condensed position O by interference.

The phase difference δ(x) at this time becomes larger as the antennas 28 move away from the condensed position O (i.e., as x increases). Therefore, the phase difference δ(x) may be set depending on the positions of the antennas 28, as illustrated in FIG. 9.

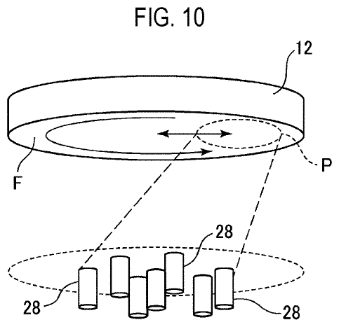

Based on this principle, the same calculation is established at an arbitrary condensed position, and the phase of each antenna 28 may be controlled based on the calculation. Therefore, as illustrated in FIG. 10, the condensed portion P including the condensed position on the irradiation surface F of the heating member 12 can be scanned only by controlling the phase shifter 24 of each antenna module 23 by the controller 30.

Conventionally, as the heating apparatus for the substrate or the like, the heating by the resistive heater as in Patent Document 1 and the heating by the lamp as in Patent Document 2 have been used. However, the heating apparatus using the resistive heater takes a long period of time to raise and lower the temperature, requiring the improvement in productivity. In addition, the controllability of the temperature distribution of the heating target object such as the substrate or the like may not be sufficient. On the other hand, since the heating apparatus using the lamp heating is very large in size, the frequency of replacing the lamp is increased and energy consumption is large, the cost is high.

In contrast, the heating apparatus according to one embodiment can condense the electromagnetic waves on an arbitrary portion of the heating member 12 by controlling the phases of the electromagnetic waves radiated from the plurality of antennas 28, and can scan the condensed portion at a very high speed, thereby efficiently heating the entire substrate at a very high speed. This increases the productivity. In addition, heating can be performed so as to have a uniform temperature distribution by scanning the condensed portion at a uniform speed, and a specific temperature distribution can also be created by changing the scanning speed of the condensed portion depending on the position of the heating member 12. In other words, the temperature distribution of the substrate as a heating target object can be freely controlled, providing very high controllability of the temperature distribution. Furthermore, since the heating apparatus using the lamp heating is large in size, the frequency of replacing the lamp is increased and the energy consumption is large, the cost is high. However, the heating using the electromagnetic wave as in the present disclosure can solve such a problem because the parts are simple and efficient.

### <Electromagnetic Field Simulation Results>

Next, the condensing of the electromagnetic waves by the phase control was confirmed by electromagnetic field simulation.

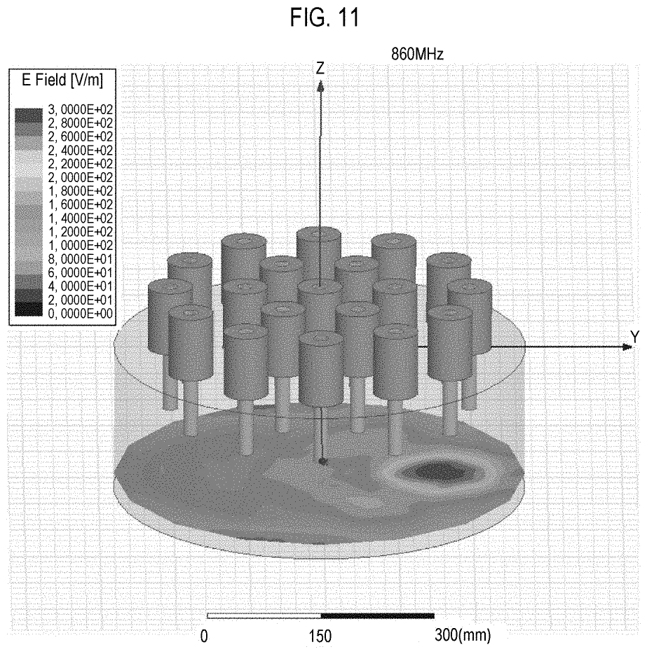

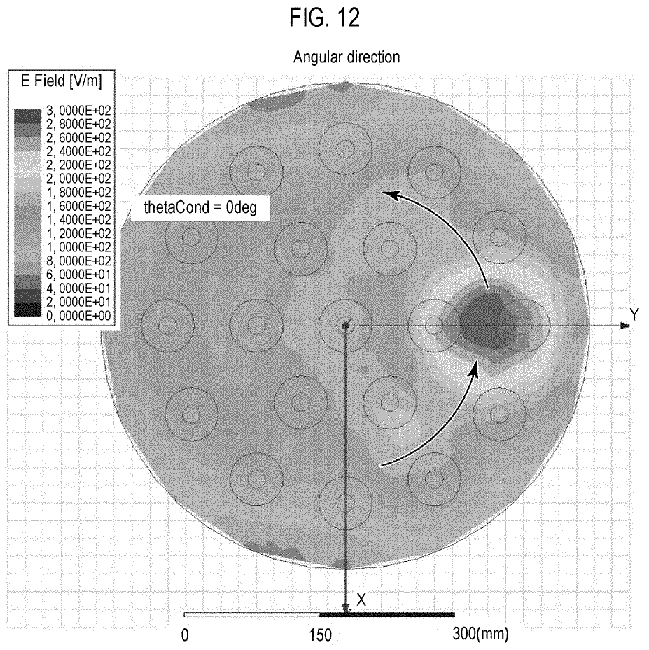

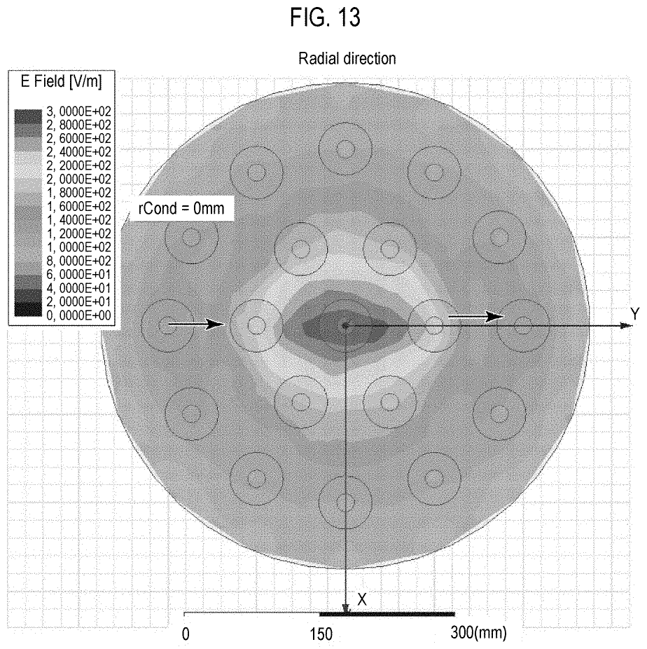

As shown in FIG. 11, simulation results obtained when 19 antenna modules are evenly arranged and an electromagnetic wave of 860 MHz is supplied to all the antenna modules with the same power are illustrated. As a result, it was confirmed that the electromagnetic wave could be condensed on an arbitrary position of the heating member (substrate) by the phase control, and that the condensed portion could be scanned by changing the phase. Specific examples are illustrated in FIGS. 12 and 13. FIG. 12 illustrates an example in which the electromagnetic wave is condensed on an outer portion of the heating member (substrate), from which it was confirmed that the condensed portion can be scanned in an angular direction by controlling the phase of the electromagnetic wave radiated from each antenna. Furthermore, FIG. 13 illustrates an example in which the electromagnetic wave is condensed on a central portion of the heating member (substrate), from which it was confirmed that the condensed portion can be scanned in a radial direction by controlling the phase of the electromagnetic wave radiated from each antenna.

### <Example of the Substrate Processing Apparatus Including the Heating Apparatus>

Next, an example of a substrate processing apparatus including the heating apparatus according to one embodiment described above will be described.

In this example, a film-forming apparatus which performs a film-forming process by CVD while heating the substrate S with the heating apparatus will be described as an example of the substrate processing apparatus.

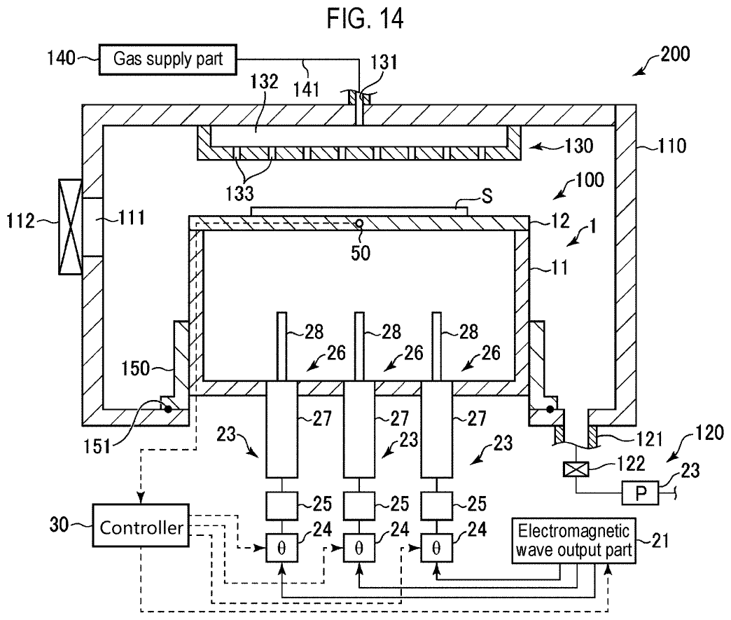

FIG. 14 is a cross-sectional view illustrating an example of the substrate processing apparatus including the heating apparatus according to one embodiment. A substrate processing apparatus 200 of this example includes a vacuumable chamber 110, and further includes the heating apparatus 100 having the aforementioned configuration provided in a lower portion of the chamber 110. In addition, the substrate processing apparatus 200 includes an exhaust part 120 installed below the chamber 110, a shower head 130 installed in an upper portion of the chamber 110, and a gas supply part 140 for supplying a gas such as a processing gas or the like to the shower head 130. A loading/unloading port 111 for loading and unloading the substrate S therethrough is formed in a sidewall of the chamber 110. The loading/unloading port 111 is configured to be opened and closed by a gate valve 112. Furthermore, the stage housing 1 of the heating apparatus 100 is attached to the lower portion of the chamber 110 by a support member 150. A seal ring 151 is interposed between the support member 150 and the lower portion of the chamber 110.

The exhaust part 120 has an exhaust pipe 121 connected to the bottom of the chamber 110, a pressure control valve (APC) 122 installed in the exhaust pipe 121, and a vacuum pump 123 for exhausting the interior of the chamber 110 via the exhaust pipe 121.

The shower head 130 is attached to a ceiling wall of the chamber 110, and has a gas introducing hole 131 provided at its upper portion and a gas diffusion space 132 formed therein. A plurality of gas discharge holes 133 is formed on a lower surface of the shower head 130.

Furthermore, the gas supply part 140 is configured to supply a processing gas for forming a predetermined film on the substrate S or an inert gas for purging the interior of the chamber 110 from the gas introducing hole 131 into the shower head 130 via the pipe 141. The gas supply part 140 serves as a processing mechanism.

In the substrate processing apparatus 200 configured as above, the gate valve 112 is opened, and the substrate S is loaded from an adjacent vacuum transfer chamber via the loading/unloading port 111 by a transfer device (all not shown) and is placed on the heating member 12 of the heating apparatus 100. Then, the interior of the chamber 110 is adjusted to have a predetermined degree of vacuum by the exhaust part 120. Furthermore, the placement of the substrate S on the heating member 12 is performed by elevating pins (not shown) installed so as to be moved upward and downward on the heating member 12.

In this state, the substrate S on the heating member 12 is heated by the heating apparatus 100 as described above. That is, the electromagnetic wave is irradiated from the electromagnetic wave irradiation part 2 provided below the heating member 12 toward the lower surface of the heating member 12 to heat the heating member 12, so that the substrate S is heated by heat of the heating member 12.

At this time, in the plurality of antenna modules 23 constituting the antenna unit 22, by controlling the phases of the electromagnetic waves radiated from the antennas 28, the electromagnetic waves are locally condensed, and the condensed portion is quickly scanned. Thus, the substrate S can be uniformly heated to a desired temperature at a very high speed.

In this state, the processing gas is supplied from the gas supply part 140 to the shower head 130, and is introduced into the chamber 110 via the shower head 130. Thus, a predetermined film is formed on the substrate S.

After the film formation, the irradiation of the electromagnetic wave is turned off, and then the gate valve 112 is opened and the substrate S is unloaded from the loading/unloading port 111 to the vacuum transfer chamber (not shown) by the transfer device (not shown).

### <Other Applications>

In the above, one embodiment has been described above, but it should be noted that the embodiment disclosed herein is exemplary in all respects and are not restrictive. The above-described embodiment may be omitted, replaced or modified in various forms without departing from the scope and spirit of the appended claims.

For example, the configuration of the antenna modules is not limited to the aforementioned embodiment. For example, the phase shifter may be installed on the side of the antenna rather than the side of the amplifier part. Furthermore, the configuration of the electromagnetic wave output part is not limited to the aforementioned embodiment.

Moreover, in the aforementioned embodiment, there has been described an example in which a CVD film-forming apparatus is used as the substrate processing apparatus to which the heating apparatus is applied. However, the present disclosure is not limited thereto. For example, a PVD film-forming apparatus, a gas etching apparatus, or the like may be used as the substrate processing apparatus as long as it can process the substrate while heating the substrate.

Furthermore, in the aforementioned embodiment, there has been described an example in which the substrate is used as the heating target object, but the heating target object is not limited to the substrate. In addition, the substrate as the heating target object, applied to the substrate processing apparatus, is not particularly limited but various substrates such as a semiconductor wafer, a flat panel display (FPD) substrate, a ceramic substrate and the like may be applied.

According to the present disclosure in some embodiments, it is possible to provide a heating apparatus, a heating method, and a substrate processing apparatus, which are capable of raising and lowering a temperature of an heating target object in a short period of time, and which are compact and low in apparatus cost.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A heating apparatus for heating a heating target object, comprising:
a heating member configured to support the heating target object and made of an electromagnetic wave absorber;
an electromagnetic wave irradiation part configured to irradiate an electromagnetic wave to an irradiation surface of the heating member positioned opposite to a surface supporting the heating target object; and
a controller,
wherein the electromagnetic wave irradiation part comprises:
an electromagnetic wave output part configured to output the electromagnetic wave; and
an antenna unit constituting a phased array antenna,
the antenna unit further comprises:
a plurality of antenna modules each having an antenna configured to radiate the electromagnetic wave and a phase shifter configured to adjust a phase of the electromagnetic wave radiated from the antenna, and
the controller is configured to control the phase shifters of the plurality of antenna modules so that phases of electromagnetic waves radiated from a plurality of the antenna are condensed on an arbitrary portion of the heating member by interference, and a condensed portion of the electromagnetic waves is scanned on the irradiation surface of the heating member.

2. The heating apparatus of claim 1, wherein the heating member is made of a carbon-based material.

3. The heating apparatus of claim 2, wherein the antenna is a monopole antenna.

4. The heating apparatus of claim 3, wherein the antenna unit further comprises a conductive connection member configured to connect adjacent antennas of the plurality of antennas installed in the plurality of antenna modules.

5. The heating apparatus of claim 4, wherein the controller is configured to control a scanning speed of the condensed portion so that the heating target object has a uniform temperature distribution.

6. The heating apparatus of claim 5, wherein the heating target object is a substrate.

7. The heating apparatus of claim 1, wherein the antenna is a monopole antenna.

8. The heating apparatus of claim 1, wherein the controller is configured to control a scanning speed of the condensed portion so that the heating target object has a uniform temperature distribution.

9. The heating apparatus of claim 1, wherein the controller is configured to change a scanning speed of the condensed portion so that the heating target object has a specific temperature distribution.

10. The heating apparatus of claim 1, wherein the heating target object is a substrate.

11. A method of heating a heating target object, the method comprising:
supporting the heating target object by a heating member made of an electromagnetic wave absorber;
supplying an electromagnetic wave to an antenna unit constituting a phased array antenna which includes a plurality of antenna modules each having an antenna configured to radiate the electromagnetic wave and a phase shifter configured to adjust a phase of the electromagnetic wave radiated from the antenna, and radiating the electromagnetic waves from a plurality of the antenna; and
controlling the phase shifters of the plurality of antenna modules so that phases of electromagnetic waves radiated from the plurality of antennas are condensed on an arbitrary portion of the heating member through interference, and a condensed portion of the electromagnetic waves is scanned on an irradiation surface of the heating member.

12. The method of claim 11, wherein the heating member is made of a carbon-based material.

13. The method of claim 12, wherein the antenna is a monopole antenna.

14. The method of claim 13, wherein the antenna unit further comprises a conductive connection member configured to connect adjacent antennas of the plurality of antennas installed in the plurality of antenna modules.

15. The method of claim 14, further comprising: controlling a scanning speed of the condensed portion so that the heating target object has a uniform temperature distribution.

16. The method of claim 15, wherein the heating target object is a substrate.

17. The method of claim 11, wherein the antenna is a monopole antenna.

18. The method of claim 11, further comprising: controlling the heating target object to have a specific temperature distribution by changing a scanning speed of the condensed portion.

19. The method of claim 11, wherein the heating target object is a substrate.

20. A substrate processing apparatus for performing a process on a substrate while heating the substrate, comprising:
a chamber in which the substrate is accommodated;
the heating apparatus of claim 1, which heats the substrate as an heating target object; and
a processing mechanism configured to process the substrate,
wherein the process is performed on the substrate while heating the substrate with the heating apparatus.
